(19) United States
(12) Patent Application Publication
(10) Pub. No.: US 2026/0238198 A1
(43) Pub. Date: Aug. 13, 2026

(54) DC COMPONENT EXTRACTION APPARATUS, DC COMPONENT EXTRACTION METHOD, AND DEMODULATION APPARATUS

(71) Applicant: KABUSHIKI KAISHA TOSHIBA, Kawasaki-shi (JP)

(72) Inventor: Tatsuhiko GOTO, Kawasaki Kanagawa (JP)

(73) Assignee: KABUSHIKI KAISHA TOSHIBA, Kawasaki-shi (JP)

(21) Appl. No.: 19/463,314

(22) Filed: Jan. 29, 2026

(30) Foreign Application Priority Data
Feb. 7, 2025 (JP) 2025-019429

(51) Int. Cl. H03K 5/01; H03K 5/00; H03K 5/1252; H03K 5/24

(52) U.S. Cl. CPC H03K 5/01; H03K 5/1252; H03K 5/24; H03K 2005/00078

(57) ABSTRACT

According to one embodiment, a DC component extraction apparatus includes a first and a second Hilbert transformer, a first and a second delay unit, and an adder. The first Hilbert transformer applies a phase shift of 90° to an input signal. The second Hilbert transformer applies a phase shift of 90° to a signal output from first Hilbert transformer to generate a filtered signal. The first delay unit delays the input signal by a delay time corresponding to the first Hilbert transformer. The second delay unit delays a signal output from the first delay unit by a delay time corresponding to the second Hilbert transformer to generate a delay signal. The adder adds the filtered signal and the delay signal.

### CROSS-REFERENCE TO RELATED APPLICATIONS

This application is based upon and claims the benefit of priority from Japanese Patent Application No. 2025-019429, filed Feb. 7, 2025, the entire contents of which are incorporated herein by reference.

### FIELD

Embodiments described herein relate generally to a DC component extraction apparatus, a DC component extraction method, and a demodulation apparatus.

### BACKGROUND

There are many needs to extract a direct current (DC) component from a signal. The simplest way to extract the DC component from the signal is to apply a moving average. In addition, it is also generally used to apply a low-pass filter in order to suppress periodic components other than the DC component. However, in a case where the periodic component is configured at a low frequency or in a case where the DC component is frequently switched, these methods may not be able to follow the change in the DC component.

### BRIEF DESCRIPTION OF DRAWINGS

FIG. 1 is a block diagram illustrating a DC component extraction apparatus according to an embodiment.

FIG. 2 is a diagram illustrating filter characteristics of the DC component extraction apparatus illustrated in FIG. 1.

FIG. 3 is a diagram illustrating an envelope of the filter characteristics illustrated in FIG. 2.

FIG. 4 is a diagram illustrating a relationship between a filter length and a lower limit frequency obtained from a graph illustrated in FIG. 3.

FIG. 5 is a diagram illustrating a relationship between a filter length and a lower limit frequency obtained from the graph illustrated in FIG. 3.

FIG. 6 is a diagram illustrating an example in which a DC component is extracted from an input signal using the DC component extraction apparatus illustrated in FIG. 1.

FIG. 7 is an enlarged view of a part of the graph of FIG. 6.

FIG. 8 is a block diagram illustrating a DC component extraction apparatus according to an embodiment.

FIG. 9 is a diagram illustrating a signal input to a comparator illustrated in FIG. 8.

FIG. 10 is a diagram illustrating an algorithm in which the comparator according to the embodiment switches an output signal.

FIG. 11 is a diagram illustrating an example in which a DC component is extracted from an input signal using the DC component extraction apparatus illustrated in FIG. 8.

FIG. 12 is an enlarged view of a part of a graph of FIG. 11.

FIG. 13 is a block diagram illustrating a DC component extraction apparatus according to an embodiment.

FIG. 14 is a diagram illustrating a signal input to a comparator illustrated in FIG. 13.

FIG. 15 is a diagram illustrating an example in which a DC component is extracted from an input signal using the DC component extraction apparatus illustrated in FIG. 13.

FIG. 16 is an enlarged view of a part of a graph of FIG. 15.

FIG. 17 is a diagram illustrating a signal generated from the input signal in which the DC component is switched in a minimum switching period in the DC component extraction apparatus illustrated in FIG. 13.

FIG. 18 is a diagram illustrating a DC component extracted from an input signal in which the DC component is switched in a minimum switching period in the DC component extraction apparatus illustrated in FIG. 13.

FIG. 19 is a diagram illustrating an algorithm according to the embodiment in which a comparator to which a chattering prevention measure is applied switches the output signal.

FIG. 20 is a diagram illustrating an example in which a DC component is extracted from an input signal using the DC component extraction apparatus illustrated in FIG. 13.

FIG. 21 is a diagram illustrating the DC component illustrated in FIG. 20.

FIG. 22 is an enlarged view of a part of a graph of FIG. 21.

FIG. 23 is an enlarged view of a part of the graph of FIG. 21.

FIG. 24 is a diagram illustrating an example of extracting a DC component from an input signal using a DC component extraction apparatus in which a chattering prevention measure is applied to the comparator illustrated in FIG. 13.

FIG. 25 is a diagram illustrating the DC component illustrated in FIG. 24.

FIG. 26 is a diagram illustrating a modification of the DC component extraction apparatus according to the embodiment.

FIG. 27 is a block diagram illustrating a demodulation apparatus using the DC component extraction apparatus according to the embodiment.

FIG. 28 is a diagram illustrating an example of a signal input to the demodulation apparatus illustrated in FIG. 27.

FIG. 29 is a diagram illustrating a signal obtained by multiplying an acquisition signal illustrated in FIG. 28 by a sinusoidal signal and a DC component extracted from the signal.

FIG. 30 is a diagram illustrating a signal obtained by multiplying the acquisition signal illustrated in FIG. 28 by a cosine signal and a DC component extracted from the signal.

FIG. 31 is a diagram illustrating the DC component illustrated in FIGS. 29 and 30.

FIG. 32 is a diagram illustrating a part of a graph of FIG. 31.

FIG. 33 is a diagram illustrating a part of the graph of FIG. 31.

FIG. 34 is a diagram illustrating a part of the graph of FIG. 31.

FIG. 35 is a diagram illustrating a result obtained by demodulating the acquisition signal illustrated in FIG. 28.

FIG. 36 is a diagram illustrating a part of a graph of FIG. 35.

FIG. 37 is a diagram illustrating a signal obtained by multiplying the acquisition signal illustrated in FIG. 28 by a sinusoidal signal and a DC component extracted from the signal in a case where a chattering prevention method is adopted.

FIG. 38 is a diagram illustrating a signal obtained by multiplying the acquisition signal illustrated in FIG. 28 by a cosine signal and a DC component extracted from the signal in a case where the chattering prevention method is adopted.

FIG. 39 is a diagram illustrating a result obtained by demodulating the acquisition signal illustrated in FIG. 28 in a case where the chattering prevention method is adopted.

FIG. 40 is a block diagram illustrating a computer according to an embodiment.

### DETAILED DESCRIPTION

According to one embodiment, a DC component extraction apparatus includes a first Hilbert transformer, a second Hilbert transformer, a first delay unit, a second delay unit, and a first adder. The first Hilbert transformer is configured to apply a phase shift of 90° to an input signal to generate a first filtered signal. The second Hilbert transformer is configured to apply a phase shift of 90° to the first filtered signal to generate a second filtered signal. The first delay unit is configured to delay the input signal by a delay time corresponding to the first Hilbert transformer to generate a first delay signal. The second delay unit is configured to delay the first delay signal by a delay time corresponding to the second Hilbert transformer to generate a second delay signal. The first adder is configured to add the second filtered signal and the second delay signal.

According to one embodiment, there are provided a DC component extraction apparatus and a DC component extraction method that can easily extract a DC component from a signal, and a demodulation apparatus using the DC component extraction apparatus.

Hereinafter, embodiments will be described with reference to the accompanying drawings.

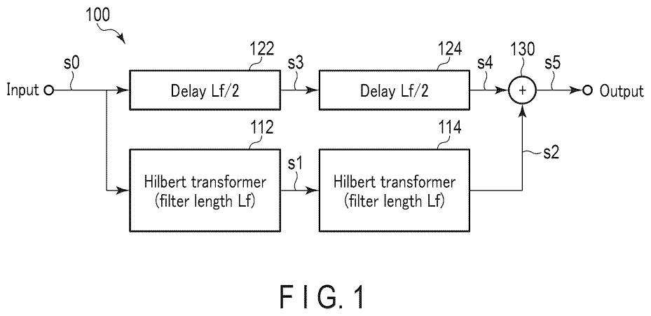

FIG. 1 schematically illustrates a DC component extraction apparatus 100 according to an embodiment. The DC component extraction apparatus 100 may be a digital filter that extracts a DC component from a signal. As shown in FIG. 1, the DC component extraction apparatus 100 includes a Hilbert transformer 112, a Hilbert transformer 114, a delay unit 122, a delay unit 124, and an adder 130.

An input of the DC component extraction apparatus 100 is connected to an input of the Hilbert transformer 112 and an input of the delay unit 122. An output of Hilbert transformer 112 is connected to an input of the Hilbert transformer 114, and an output of the Hilbert transformer 114 is connected to the first input of adder 130. An output of the delay unit 122 is connected to an input of the delay unit 124, and an output of the delay unit 124 is connected to a second input of the adder 130. An output of the adder 130 is connected to an output of the DC component extraction apparatus 100.

An input signal s0 is bifurcated and supplied to the Hilbert transformer 112 and the delay unit 122. For example, the input signal s0 is provided to the Hilbert transformer 112 and a duplicate of the input signal s0 is provided to the delay unit 124. The input signal s0 is, for example, a digital signal obtained by sampling an analog signal (for example, a voltage signal) from which a DC component is to be extracted, at a sampling frequency Fs.

The Hilbert transformer 112 applies a phase shift of 90° (π/2 radians) to the input signal s0 to generate a signal s1. For example, the Hilbert transformer 112 delays the input signal s0 by a phase of 90°. The Hilbert transformer 112 gives a phase delay of 90° only to a periodic component included in input signal s0, and does not output the DC component included in the input signal s0. The periodic component is also called an AC (alternating current) component or a frequency component. Thus, the signal s1 output from the Hilbert transformer 112 does not include a DC component. The Hilbert transformer 112 may be implemented using a finite impulse response (FIR) filter. If the Hilbert transformer 112 is an FIR type Hilbert transformer, then the Hilbert transformer 112 includes a delay of Lf/2Fs. In other words, the Hilbert transformer 112 delays the signal by a time of Lf/2Fs. Here, Lf is a filter length.

The Hilbert transformer 114 has the same configuration as that of the Hilbert transformer 112. Therefore, a specific description of the Hilbert transformer 114 is omitted. The Hilbert transformer 114 applies a phase shift of 90° to signal s1 to generate a signal s2.

The delay unit 122 delays the input signal s0 by a delay time Lf/2Fs corresponding to the Hilbert transformer 112 to generate a signal s3. The delay unit 124 delays the signal s3 by a delay time Lf/2Fs corresponding to the Hilbert transformer 114 to generate a signal s4.

The adder 130 adds the signal s2 output from the Hilbert transformer 114 and the signal s4 output from the delay unit 124 to generate a signal s5. Since the input signal s0 is passed through the two Hilbert transformers 112 and 114, the DC component of the signal s2 output from the Hilbert transformer 114 is removed, and a phase of the periodic component is delayed by 180° with respect to the signal s4. Therefore, by adding the signal s2 to the signal s4, the periodic component included in the signal s4 is canceled by the signal s2, and the DC component included in the signal s4 is extracted as the signal s5. The signal s5 output from the adder 130 is an output signal of the DC component extraction apparatus 100.

In a case where an FIR type Hilbert transformer with a filter length of Lf is used as each of the Hilbert transformers 112 and 114, a series of processing described above for the DC component extraction apparatus 100 can be performed by an FIR filter with a filter length of 2×Lf−1, described below.
(delay Lf)+(Hilbert transformer) * (Hilbert transformer)

Here, * represents convolution. That is, the Hilbert transformer 112, the Hilbert transformer 114, the delay unit 122, the delay unit 124, and the adder 130 can be implemented as a single filter. Here, this filter is referred to as a double Hilbert filter.

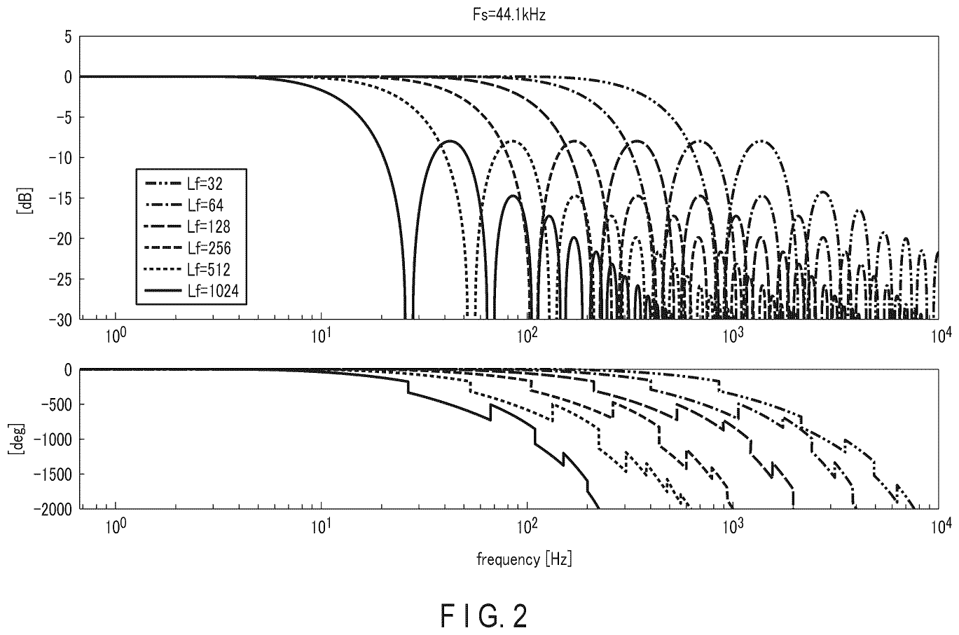

FIG. 2 schematically illustrates filter characteristics of the DC component extraction apparatus 100. From FIG. 2, it can be confirmed that the DC component extraction apparatus 100 can reduce periodic components other than the DC component. By increasing a filter length Lf, a lower limit frequency of the periodic component that can be reduced can be reduced. However, in a case where the filter length Lf is increased, the time delay (delay corresponding to the filter length Lf) is increased.

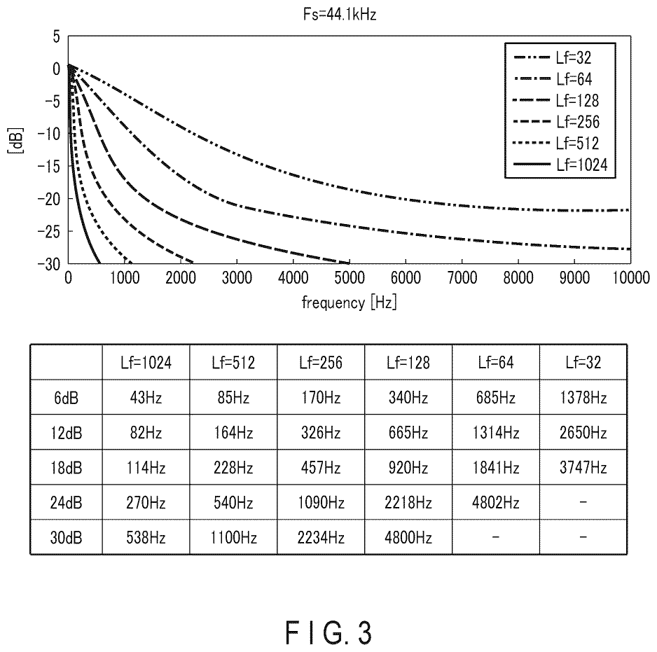

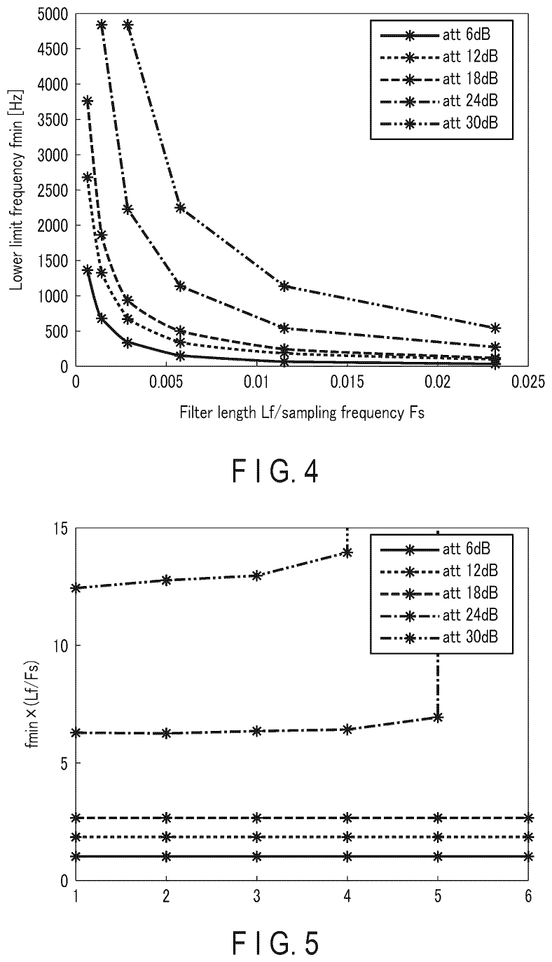

FIG. 3 schematically illustrates the envelope of the filter characteristics illustrated in FIG. 2, and FIGS. 4 and 5 schematically illustrate the relationship between the filter length Lf and the lower limit frequency in a case where the reduction effects (att) of 6 dB, 12 dB, 18 dB, 24 dB, and 30 dB obtained from the envelope illustrated in FIG. 3 are obtained. In a case where the reduction effect is estimated from the graphs illustrated in FIGS. 4 and 5 obtained from the envelope of the filter characteristics illustrated in FIG. 3, a relationship between the filter length Lf and the lower limit frequency is roughly expressed by the following expression.

$$α = fmin \times Lf / Fs$$

Here, fmin is a lower limit frequency [Hz], and α is a parameter representing a reduction effect on the periodic component. As illustrated in FIG. 5, for example, in a case where a reduction effect of 6 dB is to be obtained, α=1. In order to obtain a reduction effect of 12 dB, α=1.95. In order to obtain a reduction effect of 18 dB, α=2.7. In order to obtain a reduction effect of 24 dB, α=6.5. In order to obtain a reduction effect of 30 dB, α=13.

Therefore, it is appropriate to set the filter length Lf to a value determined according to the following expression or a value larger than the value.

$$Lf = α \times Fs / fmin$$

That is, the filter length Lf is set to satisfy the following Expression (1).

$$Lf = α \times Fs / fmin \qquad ( 1 )$$

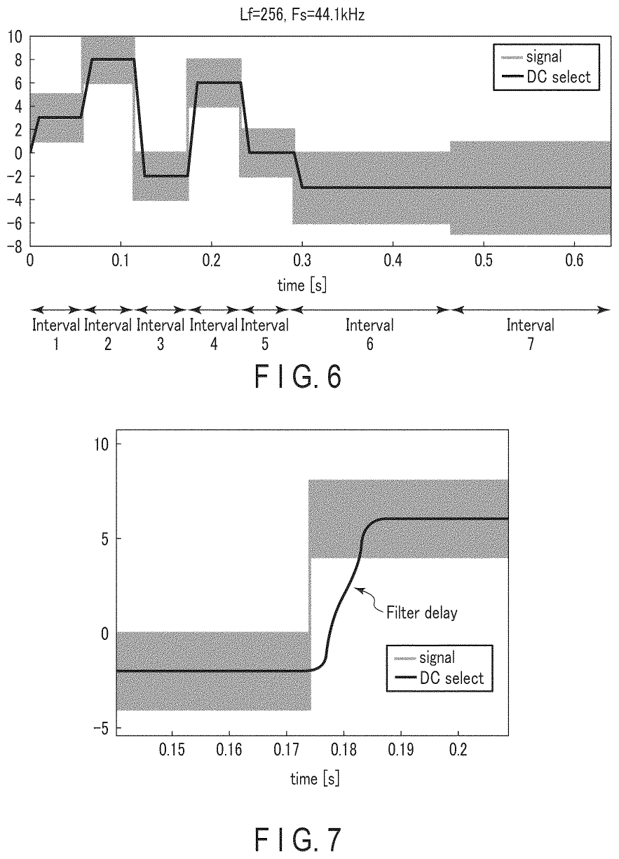

FIG. 6 schematically illustrates an example of extracting a DC component from an input signal using the DC component extraction apparatus 100, and FIG. 7 illustrates a part of the graph illustrated in FIG. 6 in an enlarged manner. In FIGS. 6 and 7, the input signal (signal) is indicated by a thin line, and the DC component (DC select) extracted from the input signal is indicated by a dark line.

The input signal changes with time as illustrated in FIG. 6. Specifically, the input signal is a signal described below.
Interval 1: 3+2sin(2000 πt)
Interval 2: 8+2sin(2000 πt)
Interval 3: −2+2sin(2000 πt)
Interval 4: 6+2sin(2000 πt)
Interval 5: 0+2sin(2000 πt)
Interval 6: −3+2sin(2000 πt)+sin(15000 πt)
Interval 7: −3+2sin(2000 πt)+2sin(1500 πt)

From FIG. 6, it can be confirmed that the DC component has been appropriately extracted. However, as illustrated in FIG. 7, a filter delay occurs when the DC component is switched. Specifically, it takes about 2 Lf/Fs for the output signal to change from −2 to 6 following the switching of the DC component in the input signal from −2 to 6.

The DC component extraction apparatus 100 having the above-described configuration can easily extract the DC component from the signal.

There is also a case where it is necessary to clearly grasp the switching of the DC component. Hereinafter, a method of removing or reducing the filter delay will be described.

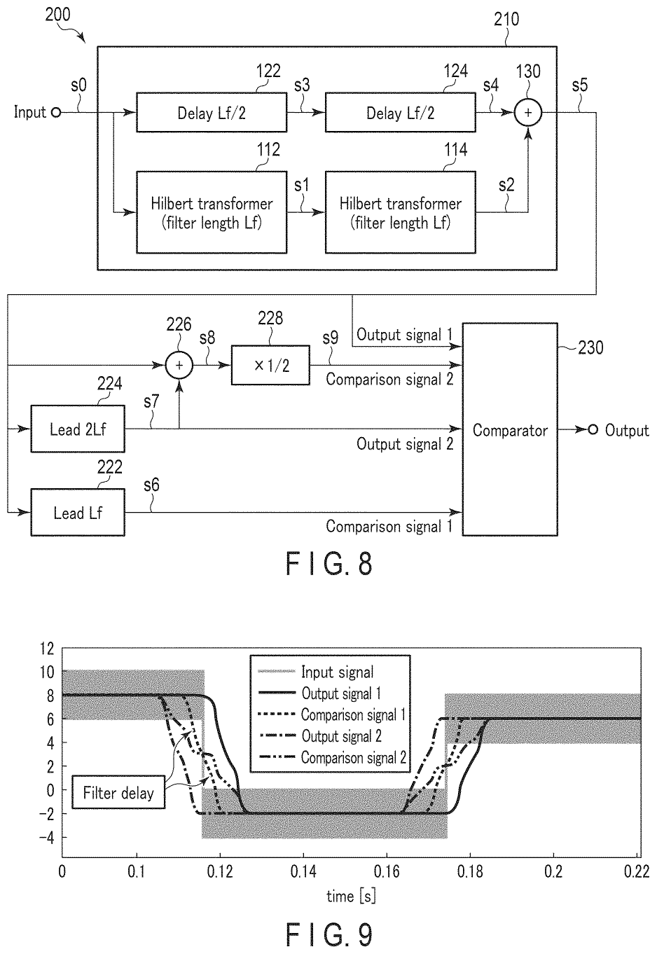

FIG. 8 schematically illustrates a DC component extraction apparatus 200 according to an embodiment. In FIG. 8, the similar portions to those illustrated in FIG. 1 are denoted by the similar reference numerals, and redundant description is appropriately omitted. The DC component extraction apparatus 200 can be used in offline processing. For example, a signal from which a DC component is to be extracted is recorded in advance, and the DC component extraction apparatus 200 extracts the DC component from the signal recorded in advance.

As illustrated in FIG. 8, the DC component extraction apparatus 200 includes a DC component extractor 210, a filter 222, a filter 224, an adder 226, an amplifier 228, and a comparator 230.

An input of the DC component extraction apparatus 200 is connected to an input of the DC component extractor 210. An output of the DC component extractor 210 is connected to an input of the filter 222, an input of the filter 224, a first input of the adder 226, and a first input of the comparator 230. An output of the filter 222 is connected to a second input of the comparator 230. An output of the filter 224 is connected to a second input of the adder 226 and a third input of the comparator 230. An output of the adder 226 is connected to an input of the amplifier 228. An output of the amplifier 228 is connected to a fourth input of the comparator 230. An output of the comparator 230 is connected to an output of the DC component extraction apparatus 200.

In the DC component extraction apparatus 200, the input signal s0 is supplied to the DC component extractor 210. The DC component extractor 210 has the same configuration as that of the DC component extraction apparatus 100 illustrated in FIG. 1, and specifically includes Hilbert transformers 112 and 114, delay units 122 and 124, and an adder 130. Therefore, a detailed description of the DC component extractor 210 is omitted. The DC component extractor 210 extracts a DC component from the input signal s0 to generate a signal s5.

The filter 222 has a lead characteristic corresponding to the filter length Lf of the Hilbert transformers 112 and 114. The filter 222 filters the signal s5 output from the DC component extractor 210 with the lead characteristic to generate a signal s6. In other words, the filter 222 causes the signal s5 to pass through the lead characteristic to generate the signal s6. The signal s6 is a signal s5 preceding by the time of Lf/Fs.

The filter 224 has a lead characteristic corresponding to twice the filter length Lf of the Hilbert transformers 112 and 114, and filters the signal s5 output from the DC component extractor 210 with the lead characteristic to generate a signal s7. The signal s7 is a signal preceding the signal s5 by a time of 2 Lf/Fs.

The adder 226 adds the signal s7 output from the filter 224 and the signal s5 output from the DC component extractor 210 to generate a signal s8. The amplifier 228 amplifies the signal s8 output from adder 226 with an amplification factor of ½ to generate a signal s9. In other words, the amplifier 228 halves the signal s8 to generate the signal s9, or attenuates the signal s8 by half to generate the signal s9.

The comparator 230 receives the signal s5 output from the DC component extractor 210 as the output signal 1, receives the signal s7 output from the filter 224 as the output signal 2, receives the signal s6 output from the filter 222 as a comparison signal 1, and receives the signal s9 output from the amplifier 228 as a comparison signal 2.

FIG. 9 schematically illustrates the comparison signal 1, the comparison signal 2, the output signal 1, and the output signal 2 generated from the input signal in the DC component extraction apparatus 200. The comparison signal 1, the comparison signal 2, the output signal 1, and the output signal 2 change with time as illustrated in FIG. 9.

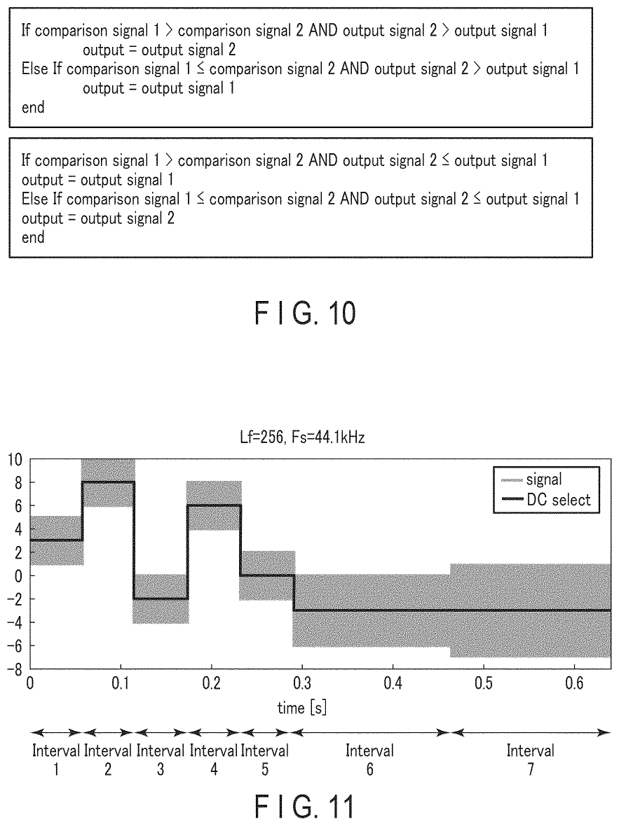

Referring back to FIG. 8, the comparator 230 switches between the output signal 1 and the output signal 2 based on the comparison between the comparison signal 1 and the comparison signal 2. Specifically, as illustrated in FIG. 10, the comparator 230 outputs the output signal 2 in a case where the comparison signal 1 is larger than the comparison signal 2 and the output signal 2 is larger than the output signal 1, outputs the output signal 1 in a case where the comparison signal 1 is equal to or smaller than the comparison signal 2 and the output signal 2 is larger than the output signal 1, outputs the output signal 1 in a case where the comparison signal 1 is larger than the comparison signal 2 and the output signal 2 is equal to or smaller than the output signal 1, and outputs the output signal 2 in a case where the comparison signal 1 is equal to or smaller than the comparison signal 2 and the output signal 2 is equal to or smaller than the output signal 1. A signal output from the comparator 230 is an output signal of the DC component extraction apparatus 200.

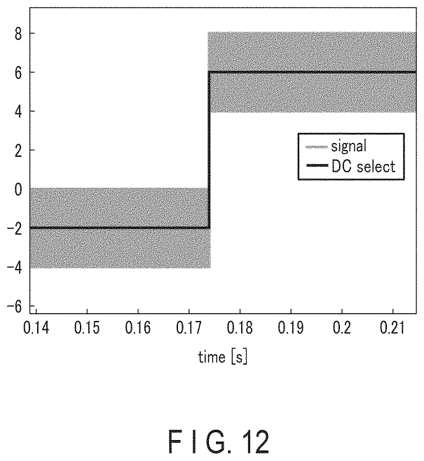

FIG. 11 schematically illustrates an example of extracting the DC component from the input signal using the DC component extraction apparatus 200, and FIG. 12 illustrates a part of the graph illustrated in FIG. 11 in an enlarged manner. In FIGS. 11 and 12, the input signal (signal) is indicated by a thin line, and the DC component (DC select) extracted from the input signal is indicated by a dark line. The input signal changes with time as illustrated in FIG. 11. Specifically, the input signal changes in a manner similar to the input signal described above with reference to FIG. 4. From FIGS. 11 and 12, it can be confirmed that the DC component extraction apparatus 200 can appropriately extract the DC component and the DC component extraction apparatus 200 can remove the filter delay.

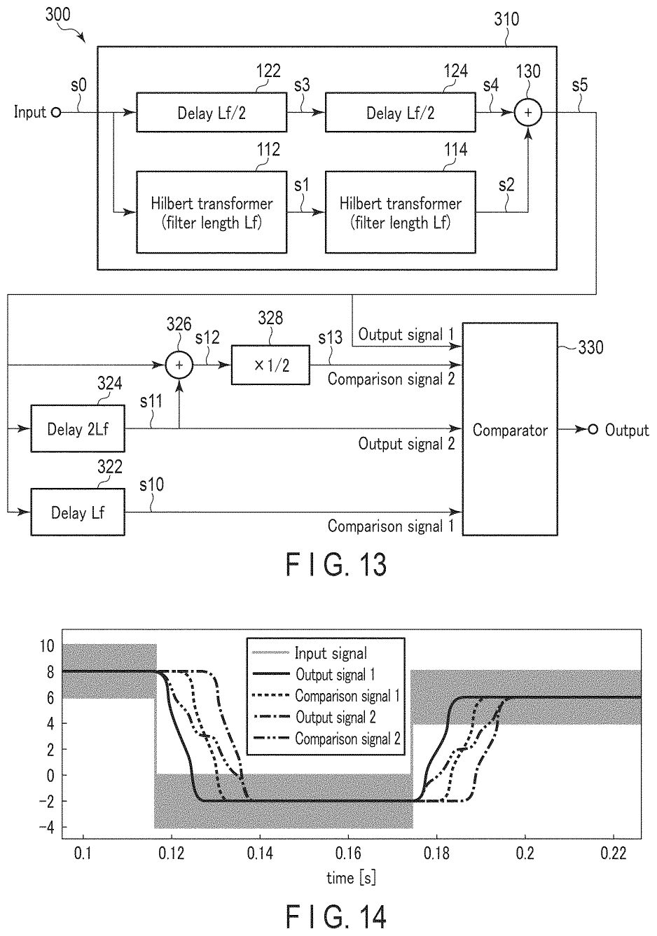

FIG. 13 schematically illustrates a DC component extraction apparatus 300 according to an embodiment. In FIG. 13, the similar portions to those illustrated in FIG. 1 are denoted by the same reference numerals, and redundant description is appropriately omitted. The DC component extraction apparatus 300 can be used in online processing. For example, a signal from which a DC component is to be extracted is supplied to the DC component extraction apparatus 300 in real time, and the DC component extraction apparatus 300 performs DC component extraction on the signal supplied in real time.

As illustrated in FIG. 13, the DC component extraction apparatus 300 includes a DC component extractor 310, a filter 322, a filter 324, an adder 326, an amplifier 328, and a comparator 330.

An input of the DC component extraction apparatus 300 is connected to an input of the DC component extractor 310. An output of the DC component extractor 310 is connected to an input of the filter 322, an input of the filter 324, a first input of the adder 326, and a first input of the comparator 330. An output of the filter 322 is connected to a second input of the comparator 330. An output of the filter 324 is connected to a second input of the adder 326 and a third input of the comparator 330. An output of the adder 326 is connected to an input of the amplifier 328. An output of the amplifier 328 is connected to a fourth input of the comparator 330. An output of the comparator 330 is connected to an output of the DC component extraction apparatus 300.

In the DC component extraction apparatus 300, the input signal s0 is supplied to the DC component extractor 310. The DC component extractor 310 has the same configuration as the DC component extraction apparatus 100 illustrated in FIG. 1, and specifically includes Hilbert transformers 112 and 114, delay units 122 and 124, and an adder 130. Therefore, a detailed description of the DC component extractor 310 is omitted. The DC component extractor 310 extracts a DC component from an input signal s0 to generate a signal s5.

The filter 322 has a delay characteristic corresponding to the filter length Lf of the Hilbert transformers 112 and 114, and filters the signal s5 output from the DC component extractor 310 with the delay characteristic to generate a signal s10. Specifically, the filter 322 is a delay unit that delays the signal by the time of Lf/Fs, and the signal s10 is a signal s5 delayed by the time of Lf/Fs.

The filter 324 has a delay characteristic corresponding to twice the filter length Lf of the Hilbert transformers 112 and 114, and filters the signal s5 output from the DC component extractor 310 with the delay characteristic to generate a signal s11. Specifically, the filter 322 is a delay unit that delays the signal by a time of 2 Lf/Fs, and the signal s12 is a signal s5 delayed by a time of 2 Lf/Fs.

The adder 326 adds the signal s11 output from the filter 324 and the signal s5 output from the DC component extractor 310 to generate a signal s12. The amplifier 328 amplifies the signal s12 output from adder 326 with an amplification factor of ½ to generate a signal s13. In other words, the amplifier 328 halves signal s12 to generate a signal s13.

The comparator 330 receives the signal s5 output from the DC component extractor 310 as an output signal 1, receives the signal s11 output from the filter 324 as an output signal 2, receives the signal s10 output from the filter 322 as a comparison signal 1, and receives the signal s13 output from the amplifier 328 as a comparison signal 2.

FIG. 14 schematically illustrates the comparison signal 1, the comparison signal 2, the output signal 1, and the output signal 2 generated from the input signal in the DC component extraction apparatus 300. The comparison signal 1, the comparison signal 2, the output signal 1, and the output signal 2 change with time as illustrated in FIG. 14.

Referring back to FIG. 13, the comparator 330 switches between the output signal 1 and the output signal 2 based on the comparison between the comparison signal 1 and the comparison signal 2. Specifically, as illustrated in FIG. 10, the comparator 330 outputs the output signal 2 in a case where the comparison signal 1 is larger than the comparison signal 2 and the output signal 2 is larger than the output signal 1, outputs the output signal 1 in a case where the comparison signal 1 is equal to or smaller than the comparison signal 2 and the output signal 2 is larger than the output signal 1, outputs the output signal 1 in a case where the comparison signal 1 is larger than the comparison signal 2 and the output signal 2 is equal to or smaller than the output signal 1, and outputs the output signal 2 in a case where the comparison signal 1 is equal to or smaller than the comparison signal 2 and the output signal 2 is equal to or smaller than the output signal 1. A signal output from the comparator 330 is an output signal of the DC component extraction apparatus 300.

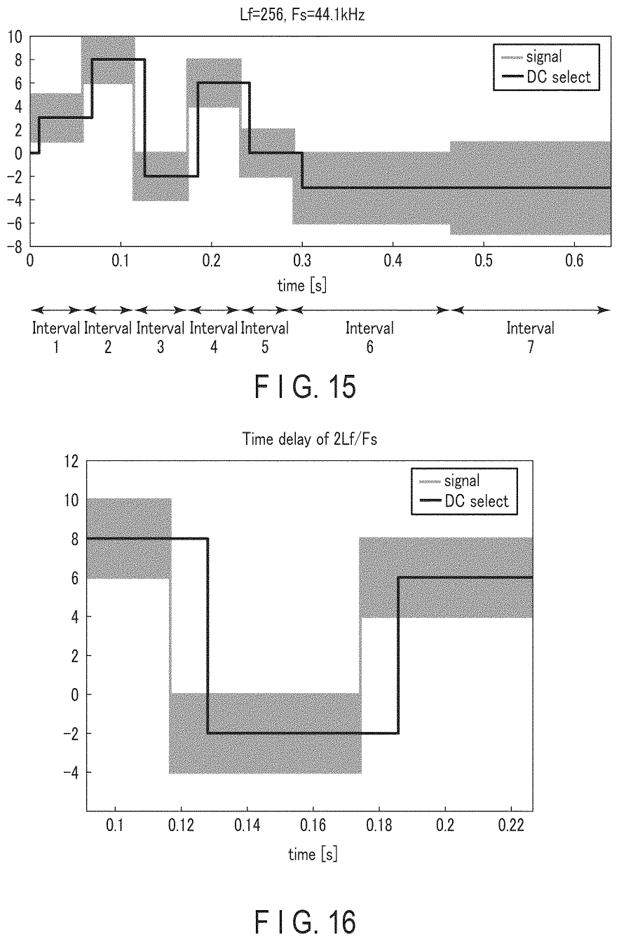

FIG. 15 schematically illustrates an example of extracting the DC component from the input signal using the DC component extraction apparatus 300, and FIG. 16 illustrates a part of the graph illustrated in FIG. 15 in an enlarged manner. In FIGS. 15 and 16, the input signal (signal) is indicated by a thin line, and the DC component (DC select) extracted from the input signal is indicated by a dark line. The input signal changes with time as illustrated in FIG. 15. Specifically, the input signal changes in a manner similar to the input signal described above with reference to FIG. 4.

From FIGS. 15 and 16, it can be confirmed that the DC component extraction apparatus 300 can appropriately extract the DC component and the DC component extraction apparatus 300 can remove the filter delay. However, because of the online processing using the delay characteristic, a dead time of 2 Lf/Fs is generated as a whole.

In the case of using the filter delay removal method described above in connection with the DC component extraction apparatuses 200 and 300, the original signal needs to continue for a time corresponding to 4×Lf. That is, a minimum switching interval of the input signal is 4×Lf/Fs. The switching interval indicates a time interval at which the DC component is switched (changed) in the input signal. For example, the switching interval corresponds to each time length of the intervals 1 to 9 described above.

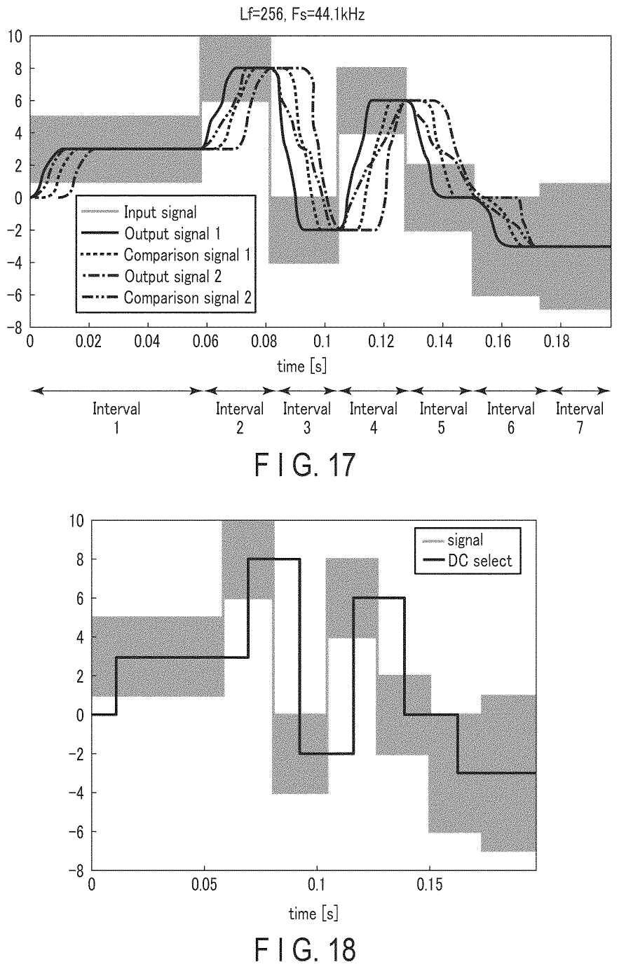

FIG. 17 schematically illustrates an input signal in which the DC component is switched in the minimum switching period and a signal generated from the input signal and input to the comparator 230, and FIG. 18 schematically illustrates an input signal in which the DC component is switched in the minimum switching period and a signal output from the comparator 230. The input signal changes with time similarly to the input signal described above with reference to FIG. 4, and the time length of the intervals 2 to 6 is set to 4 Lf/Fs. As illustrated in FIGS. 17 and 18, even in a case where the DC component is switched in the minimum switching period, the DC component can be appropriately extracted.

Assuming that the switching interval is ta, the condition that the minimum switching interval is 4×Lf/Fs can be expressed by the following Expression (2).

$$ta \geq 4 \times Lf / Fs \qquad ( 2 )$$

As described above, the filter length Lf satisfies the above Expression (1). Therefore, in the DC component extraction apparatuses 200 and 300 adopting the filter delay removal method, the filter length Lf needs to satisfy the following Expression (3).

$$ta \times Fs / 4 \geq Lf \geq α \times Fs / fmin \qquad ( 3 )$$

Expression (4) is obtained by normalizing Expression (3) with the sampling frequency Fs.

$$ta / 4 \geq Lf / Fs \geq α / fmin \qquad ( 4 )$$

For example, in a case where att=12 dB (α=1.95), Fs=44.1 kHz, fmin=300 Hz, and ta=30 msec, 330≥Lf≥287. If this condition is not satisfied, the filter delay removal method cannot be applied. In that case, a measure for changing a desired condition is taken. For example, the lower limit frequency fmin is increased, or the reduction effect att is decreased.

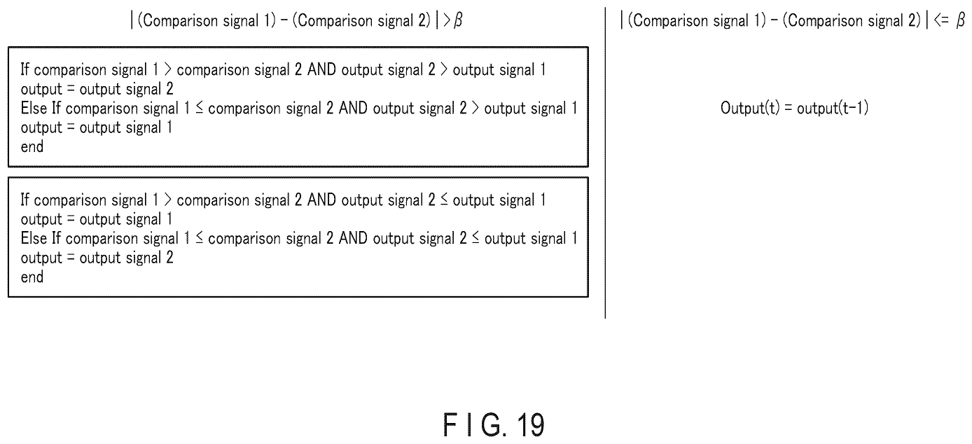

In a case where the magnitudes of the comparison signal 1 and the comparison signal 2 are frequently switched, chattering occurs in which switching between the output signal 1 and the output signal 2 frequently occurs. As a countermeasure against chattering, as illustrated in FIG. 19, a comparator corresponding to each of the comparators 230 and 330 performs processing of switching an output signal between the output signal 1 and the output signal 2 based on comparison between the comparison signal 1 and the comparison signal 2 in a case where a difference between the comparison signal 1 and the comparison signal 2 exceeds a preset threshold β, and outputs the same output signal as an output signal before one sample (1/Fs [s]) in a case where the difference between the comparison signal 1 and the comparison signal 2 is equal to or less than the preset threshold β.

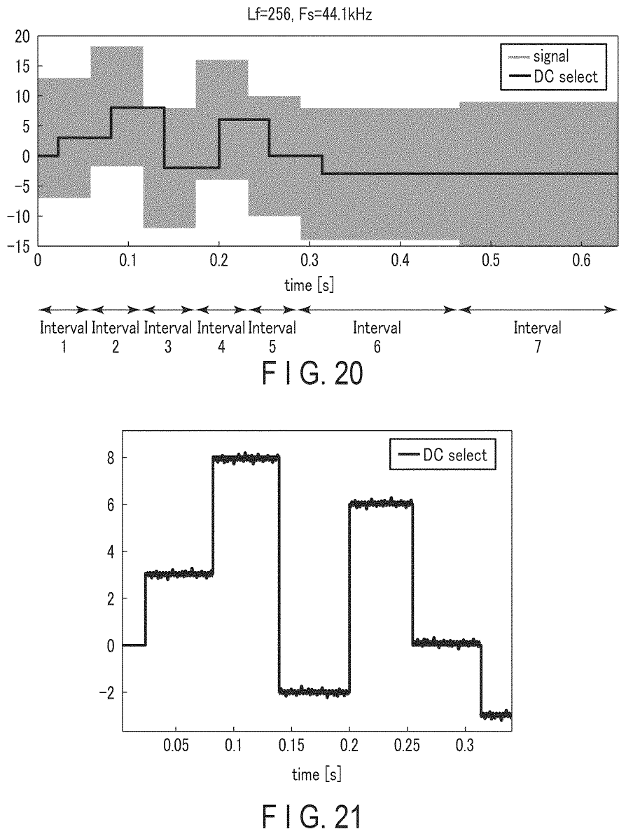

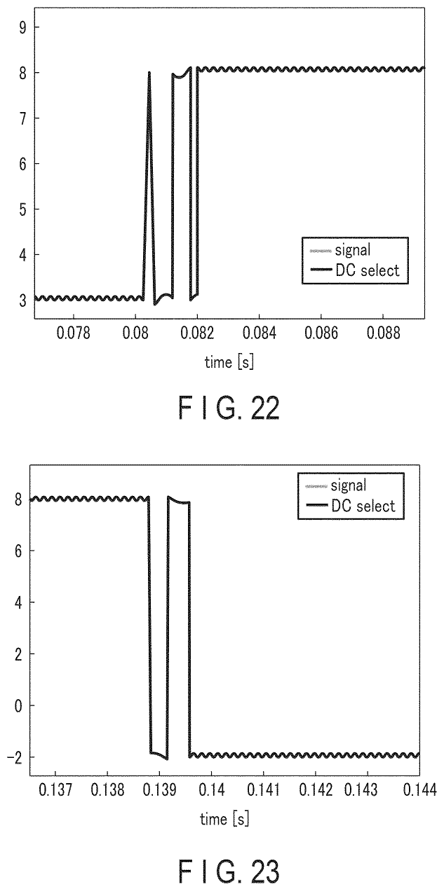

FIG. 20 schematically illustrates an example of extracting a DC component from an input signal using the DC component extraction apparatus 300, and FIG. 21 illustrates the DC component illustrated in FIG. 20 in detail. Further, FIG. 22 illustrates a portion of the graph illustrated in FIG. 21 in an enlarged manner, and FIG. 23 illustrates another portion of the graph illustrated in FIG. 21 in an enlarged manner. In FIG. 20, the input signal (signal) is indicated by a thin line, and the DC component (DC select) extracted from the input signal is indicated by a dark line. The input signal changes with time as illustrated in FIG. 20. Specifically, the input signal is a signal described below.
Interval 1: 3+10sin(2000 πt)
Interval 2: 8+10sin(2000 πt)
Interval 3: −2+10sin(2000 πt)
Interval 4: 6+10sin(2000 πt)
Interval 5: 0+10sin(2000 πt)
Interval 6: −3+10sin(2000 πt)+sin(1500 πt)
Interval 7: −3+10sin(2000 πt)+2sin(1500 πt)

From FIGS. 20 and 21, it can be confirmed that the DC component extraction apparatus 300 can appropriately extract the DC component and the DC component extraction apparatus 300 can remove the filter delay. On the other hand, as illustrated in FIGS. 22 and 23, chattering occurs.

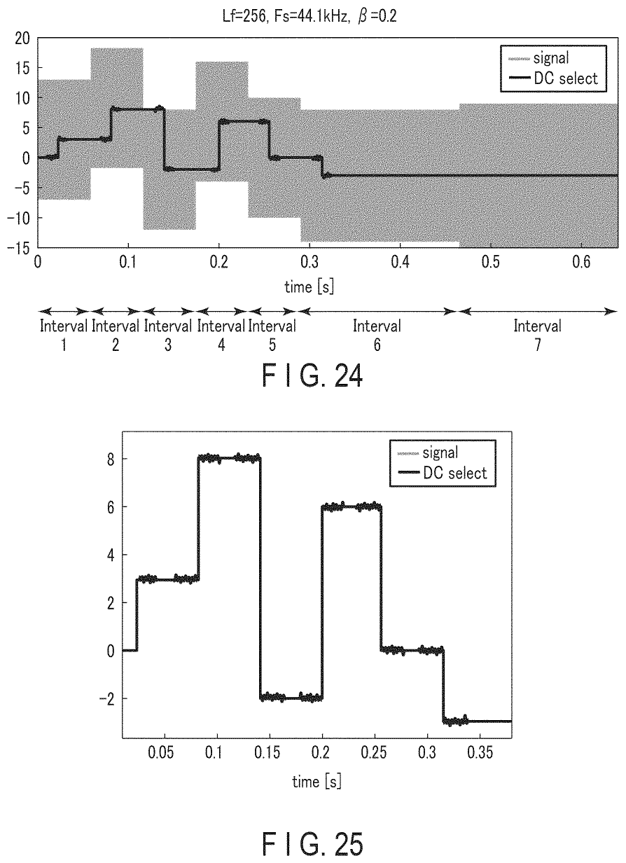

FIG. 24 schematically illustrates an example of extracting a DC component from an input signal using the DC component extraction apparatus 300 in which the comparator 330 is provided with a chattering prevention measure, and FIG. 25 illustrates the DC component illustrated in FIG. 24 in detail. Here, the threshold β is 0.2. From FIGS. 24 and 25, it can be confirmed that the DC component extraction apparatus 300 can appropriately extract the DC component, the DC component extraction apparatus 300 can remove the filter delay, and chattering can be suppressed.

The DC component extraction apparatuses according to the embodiments such as the DC component extraction apparatuses 100, 200, and 300 described above can be applied to various applications such as system identification and demodulation apparatuses.

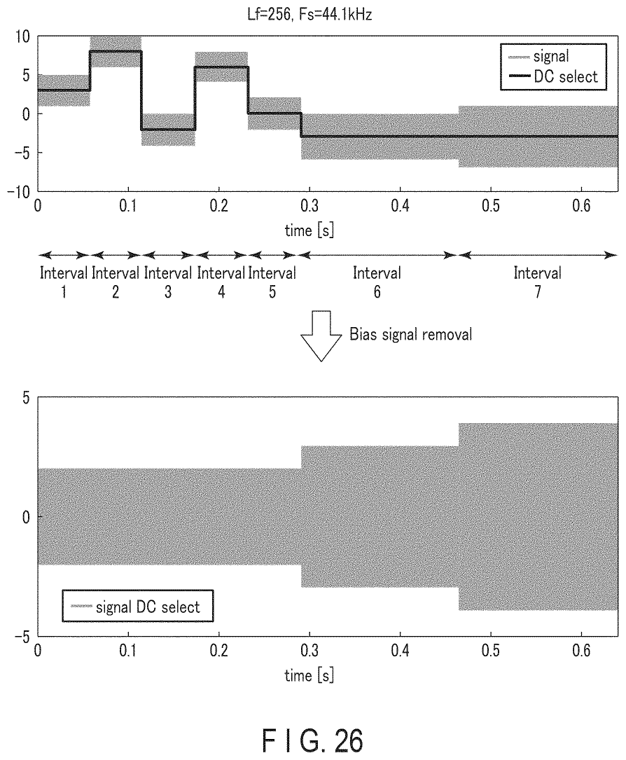

In signal processing such as system identification, in a case where an acquisition signal to be processed includes a DC component (also called a bias signal), an appropriate result may not be obtained. The DC component extraction apparatus according to the embodiment can be used to remove the DC component from the acquisition signal. Note that since the system identification is usually performed by offline processing, the above-described DC component extraction apparatus 200 can be used. For example, by extracting the DC component from a duplicate of the acquisition signal using the DC component extraction apparatus 200 and subtracting the extracted DC component from the acquisition signal, it is possible to remove the offset (bias signal) as illustrated in FIG. 26.

In addition, there is a case where it is desired to extract changes in amplitude and phase of the signal of the base frequency.

In that case, in general, the amplitude and the phase are extracted by the following demodulation processing.
1. The acquisition signal is multiplied by a sinusoidal signal (sine signal) and a cosine signal of a base frequency.
2. In order to remove a double length signal, a low-pass filter is applied to each of the two signals obtained in processing 1. In processing 2, the influence of the disturbance periodic signal is also removed.
3. A gain and a phase are obtained from the two signals obtained in processing 2, and characteristics of the original signal are demodulated.

In the above procedure, a filter delay occurs in processing 2, and a change at the time of switching may not be clearly captured.

A demodulation processing using the DC component extraction apparatus (for example, the DC component extraction apparatus 200) according to the embodiment will be described below.
1. Multiplies the acquisition signal by the sinusoidal signal and the cosine signal of the base frequency.
2. In order to remove the double length signal and the disturbance period signal, a DC component extraction apparatus 200 is applied to each of the two signals obtained in processing 1 to extract a DC component.
3. A gain and a phase are obtained from the two signals obtained in processing 2, and characteristics of the original signal are demodulated. Specifically, assuming that a signal obtained by multiplying the acquisition signal by the sinusoidal signal is signal 1 and a signal obtained by multiplying the acquisition signal by the cosine signal is signal 2, the gain and the phase are calculated from the following signals.

$$signal = signal1 + ( signal2 ) i$$

Here, i is an imaginary number. An absolute value (|signal|) of the signal indicates the amplitude, and an argument (angle (signal)) of the signal indicates the phase.

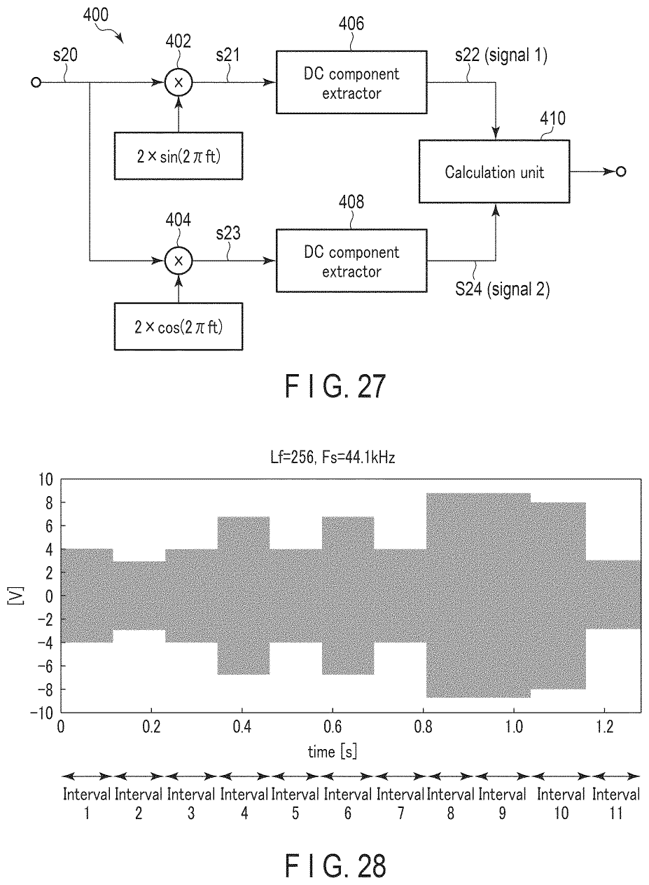

FIG. 27 schematically illustrates a demodulation apparatus 400 according to an embodiment. As illustrated in FIG. 27, the demodulation apparatus 400 includes a multiplier 402, a multiplier 404, a DC component extractor 406, a DC component extractor 408, and a calculation unit 410. In the demodulation apparatus 400, the input signal s20 to be demodulated is supplied to the multipliers 402 and 404.

The multiplier 402 multiplies the input signal s20 by a signal obtained by multiplying the sinusoidal signal of the base frequency f by 2 to generate a signal s21. The DC component extractor 406 has, for example, the same configuration as the DC component extraction apparatus 300 illustrated in FIG. 13. Note that the DC component extraction apparatus 100 illustrated in FIG. 1 may be used as the DC component extractor 406. The DC component extractor 406 extracts a DC component from the signal s21 output from the multiplier 402 to generate a signal s22.

The multiplier 404 multiplies the input signal s20 by a signal obtained by multiplying the cosine signal of a base frequency f by 2 to generate a signal s23. The DC component extractor 408 has the same configuration as that of the DC component extractor 406. The DC component extractor 408 extracts a DC component from the signal s23 output from the multiplier 404 to generate a signal s24.

The calculation unit 410 calculates a gain and a phase from the signal s22 output from the DC component extractor 406 and the signal s24 output from the DC component extractor 408. The signal S22 corresponds to the signal 1 described above, the signal S24 corresponds to the signal 2 described above, and the calculation unit 410 calculates the gain and the phase as described above.

FIG. 28 schematically illustrates an example of an acquisition signal. The acquisition signal changes with time as illustrated in FIG. 28. Specifically, the acquisition signal is a signal described below.
Interval 1: gain 6 dB, phase 30 deg, disturbance 1
Interval 2: gain 0 dB, phase 0 deg, disturbance 1
Interval 3: gain 6 dB, phase 30 deg, disturbance 1
Interval 4: gain 12 dB, phase 30 deg, disturbance 1, disturbance 2
Interval 5: gain 6 dB, phase 80 deg, disturbance 1
Interval 6: gain 12 dB, phase 30 deg, disturbance 1, disturbance 2
Interval 7: gain 6 dB, phase 80 deg, disturbance 1
Interval 8: gain 15 dB, phase −80 deg, disturbance 1, disturbance 2
Interval 9: gain 15 dB, phase 120 deg, disturbance 1, disturbance 2
Interval 10: gain 15 dB, phase 120 deg, disturbance 1
Interval 11: gain 0 dB, phase −30 deg, disturbance 1

The disturbance 1 indicates a disturbance periodic signal having a frequency of 4 kHz, and the disturbance 2indicates a disturbance periodic signal having a frequency of 5750 Hz. The base frequency is 5 kHz. For example, the acquisition signal in the interval 1 is obtained by adding a signal having a base frequency modulated with a gain of 6 dB and a phase of 30° and a disturbance periodic signal having a frequency of 4 kHz.

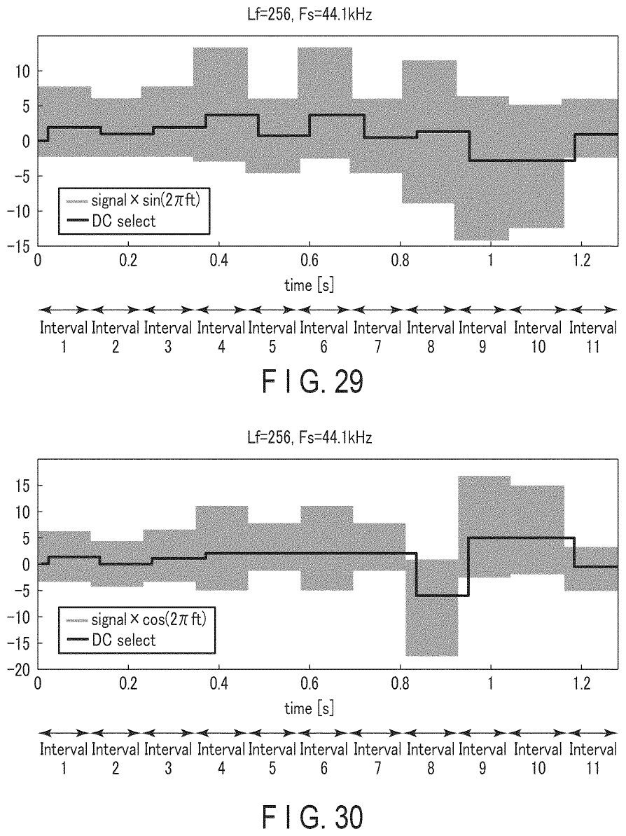

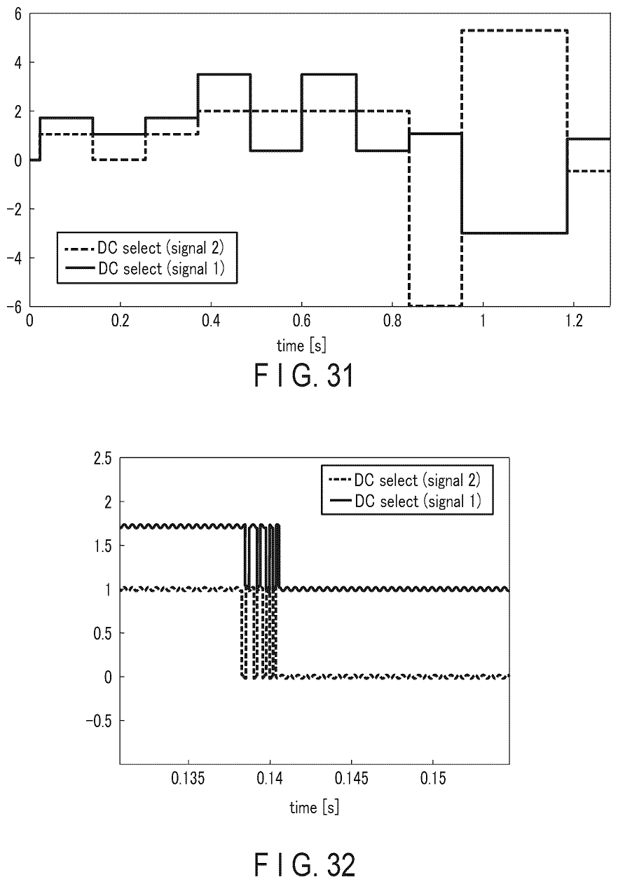

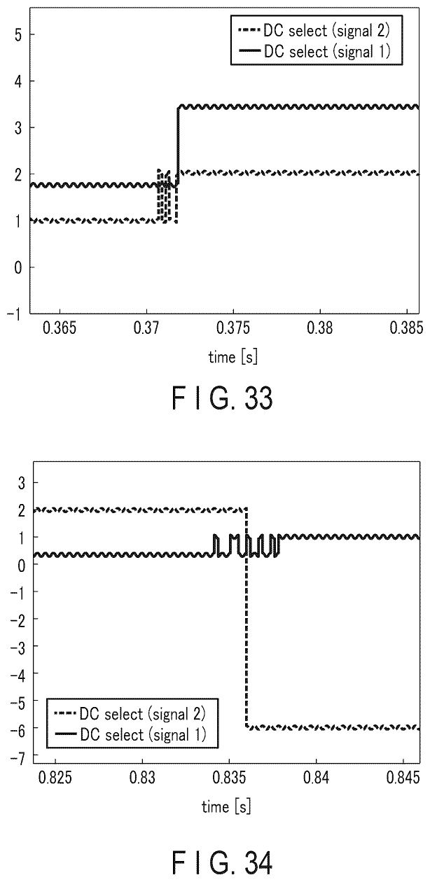

FIG. 29 schematically illustrates a signal (signal s22 output from multiplier 402) obtained by multiplying the acquisition signal illustrated in FIG. 28 by the sinusoidal signal and a DC component (signal s23 (signal 1) output from DC component extractor 406) extracted from the signal. FIG. 30 schematically illustrates a signal (signal s24 output from multiplier 404) obtained by multiplying the acquisition signal illustrated in FIG. 28 by the cosine signal and a DC component (signal s25 (signal 2) output from DC component extractor 408) extracted from the signal. FIG. 31 schematically illustrates the DC component illustrated in FIG. 29 and the DC component illustrated in FIG. 30. FIGS. 32, 33, and 34 illustrate a part of the graph illustrated in FIG. 31 in an enlarged manner. In FIGS. 31 to 34, a solid line indicates a DC component (signal 1) extracted from a signal obtained by multiplying the target signal by the sinusoidal signal, and a broken line indicates a DC component (signal 2) extracted from a signal obtained by multiplying the target signal by the cosine signal. It can be confirmed from FIGS. 32, 33, and 34 that chattering sometimes occurs in the signal 1 and the signal 2.

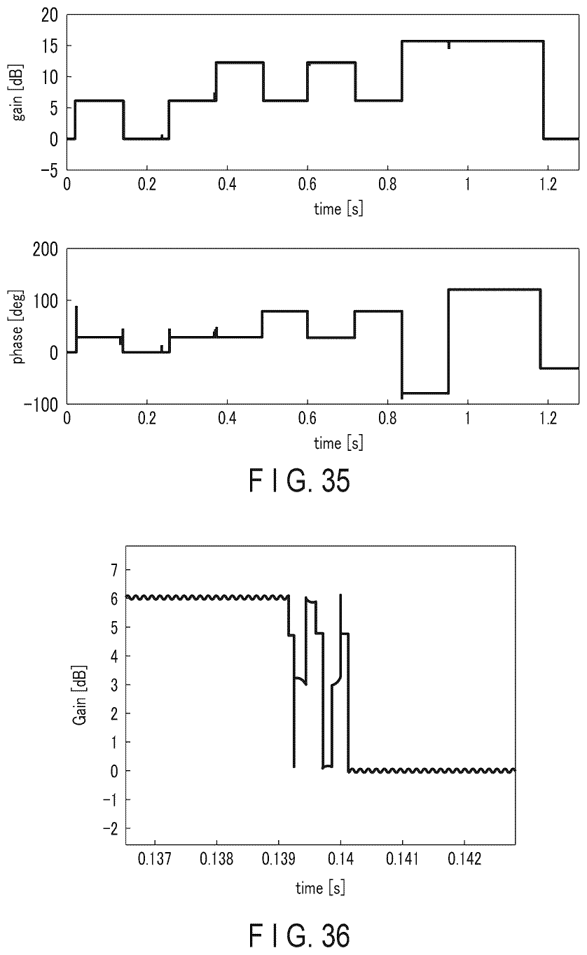

FIG. 35 schematically illustrates gains and phases obtained by demodulating the acquisition signal illustrated in FIG. 28 using the demodulation apparatus 400. From FIG. 35, it can be confirmed that demodulation can be performed with high accuracy without being affected by a disturbance periodic signal having a frequency near the base frequency.

FIG. 36 illustrates a part of the graph illustrated in FIG. 35 in an enlarged manner. As shown in FIG. 36, chattering sometimes occurs. The chattering can be suppressed by using the above-described chattering prevention method.

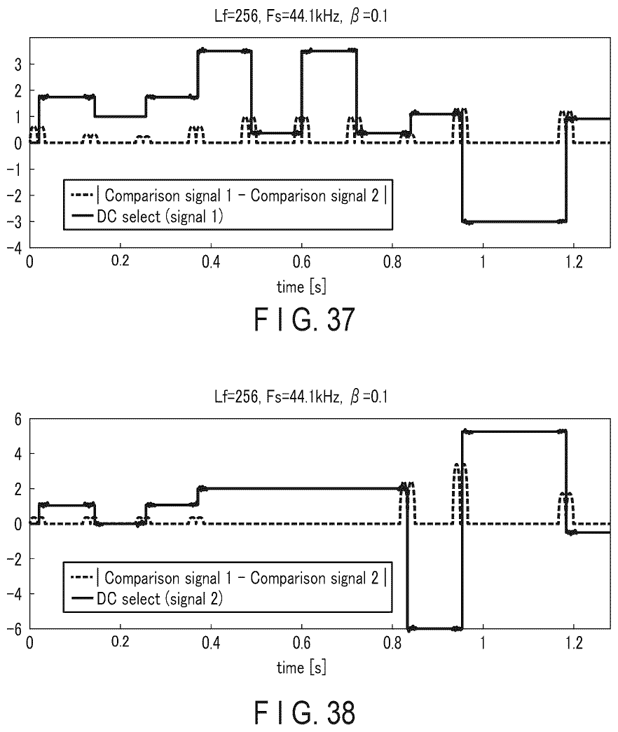

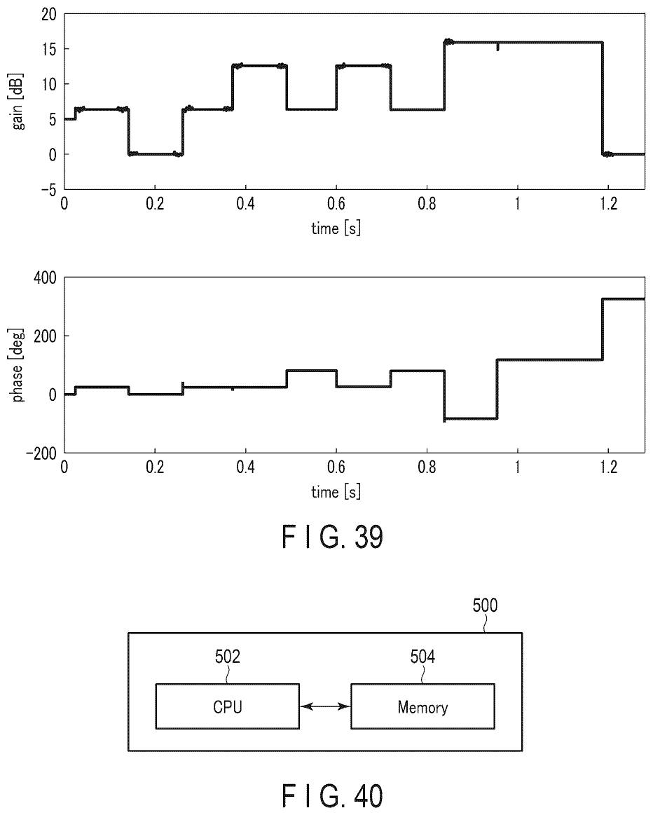

FIG. 37 schematically illustrates the DC component extracted from the signal obtained by multiplying the acquisition signal illustrated in FIG. 28 by the sinusoidal signal in the case of using the DC component extraction apparatus 300 adopting the chattering prevention method as the DC component extractor 406, and FIG. 38 schematically illustrates the DC component extracted from the signal obtained by multiplying the acquisition signal illustrated in FIG. 28 by the cosine signal in the case of using the DC component extraction apparatus 300 adopting the chattering prevention method as the DC component extraction apparatus 408. In FIGS. 37 and 38, a solid line indicates the extracted DC component, and a broken line indicates a signal obtained by subtracting a comparison signal 1 from a comparison signal 2. FIG. 39 schematically illustrates gains and phases obtained by demodulation on the acquisition signal illustrated in FIG. 28 using the demodulation apparatus 400 using the DC component extraction apparatus 300 adopting the chattering prevention method as the DC component extractors 406 and 408. From FIGS. 37 and 38, it can be confirmed that chattering can be suppressed in the extracted DC component. As a result, as illustrated in FIG. 39, chattering can be suppressed also in the demodulation result.

FIG. 40 schematically illustrates a computer 500 according to an embodiment. As illustrated in FIG. 40, a computer 500 includes, as hardware components, a central processing unit (CPU) 502 as a processing circuit, and a memory 504 connected to the CPU 502. As the processing circuit, a graphics processing unit (GPU), a digital signal processor (DSP), or a field programmable gate array (FPGA) may be used.

A series of processing described with respect to the DC component extraction apparatuses 100, 200, and 300 and the demodulation apparatus 400 may be performed by the CPU 502 executing a program stored in the memory 504. For example, the CPU 502 that executes the DC component extraction program functions as the Hilbert transformer 112, the delay units 122 and 124, and the adder 130.

The program may be provided to the computer 500 in a state of being stored in a computer-readable recording medium. In this case, the computer 500 includes a drive that reads data from a recording medium, and acquires a program from the recording medium. Examples of the recording medium include a magnetic disk, an optical disk (CD-ROM, CD-R, DVD-ROM, DVD-R, and the like), a magneto-optical disk (MO or the like), and a semiconductor memory. In addition, the program may be distributed through a network. Specifically, the program may be stored in a server on the network, and the computer 500 may download the program from the server.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A DC component extraction apparatus, comprising:
a first Hilbert transformer configured to apply a phase shift of 90° to an input signal to generate a first filtered signal;
a second Hilbert transformer configured to apply a phase shift of 90° to the first filtered signal to generate a second filtered signal;
a first delay unit configured to delay the input signal by a delay time corresponding to the first Hilbert transformer to generate a first delay signal;
a second delay unit configured to delay the first delay signal by a delay time corresponding to the second Hilbert transformer to generate a second delay signal; and
a first adder configured to add the second filtered signal and the second delay signal.

2. The DC component extraction apparatus according to claim 1, wherein the first Hilbert transformer, the second Hilbert transformer, the first delay unit, the second delay unit, and the first adder are implemented by a single filter.

3. The DC component extraction apparatus according to claim 1, wherein a filter length Lf of each of the first Hilbert transformer and the second Hilbert transformer satisfies the following condition:
$$Lf \geq α \times Fs / fmin$$
where Fs is a sampling frequency, fmin is a lower limit frequency of a periodic component to be removed, and α is a parameter according to a desired reduction effect for the periodic component.

4. The DC component extraction apparatus according to claim 1, further comprising:
a first filter configured to filter a first output signal output from the first adder with a first lead characteristic corresponding to a filter length of each of the first Hilbert transformer and the second Hilbert transformer to generate a first comparison signal;
a second filter configured to filter a first output signal output from the adder with a second lead characteristic corresponding to twice a filter length of each of the first Hilbert transformer and the second Hilbert transformer to generate a second output signal;
a second adder configured to add the first output signal and the second output signal;
an amplifier configured to halve a signal output from the second adder to generate a second comparison signal; and
a comparator configured to switch between the first output signal and the second output signal based on comparison between the first comparison signal and the second comparison signal.

5. The DC component extraction apparatus according to claim 4, wherein the comparator is configured to:
output the second output signal in a case where the first comparison signal is greater than the second comparison signal and the second output signal is greater than the first output signal;
output the first output signal in a case where the first comparison signal is less than or equal to the second comparison signal and the second output signal is greater than the first output signal;
output the first output signal in a case where the first comparison signal is greater than the second comparison signal and the second output signal is less than or equal to the first output signal; and
output the second output signal in a case where the first comparison signal is less than or equal to the second comparison signal and the second output signal is less than or equal to the first output signal.

6. The DC component extraction apparatus according to claim 1, further comprising:
a first filter configured to filter a first output signal output from the first adder with a first delay characteristic corresponding to a filter length of each of the first Hilbert transformer and the second Hilbert transformer to generate a first comparison signal;
a second filter configured to filter a first output signal output from the adder with a second delay characteristic corresponding to twice a filter length of each of the first Hilbert transformer and the second Hilbert transformer to generate a second output signal;
a second adder configured to add the first output signal and the second output signal;
an amplifier configured to halve a signal output from the second adder to generate a second comparison signal; and
a comparator configured to switch between the first output signal and the second output signal based on comparison between the first comparison signal and the second comparison signal.

7. The DC component extraction apparatus according to claim 6, wherein the comparator is configured to switches between the first output signal and the second output signal based on a comparison result between the first comparison signal and the second comparison signal and a comparison result between the first output signal and the second output signal.

8. The DC component extraction apparatus according to claim 7, wherein the comparator is configured to:
output the second output signal in a case where the first comparison signal is greater than the second comparison signal and the second output signal is greater than the first output signal;
output the first output signal in a case where the first comparison signal is less than or equal to the second comparison signal and the second output signal is greater than the first output signal;
output the first output signal in a case where the first comparison signal is greater than the second comparison signal and the second output signal is less than or equal to the first output signal; and
output the second output signal in a case where the first comparison signal is less than or equal to the second comparison signal and the second output signal is less than or equal to the first output signal.

9. The DC component extraction apparatus according to claim 4, wherein a filter length Lf of each of the first Hilbert transformer and the second Hilbert transformer satisfies the following condition:
$$ta \times Fs / 4 \geq Lf \geq α \times Fs / fmin$$
where ta is a minimum time during which a DC component is switched in the input signal, Fs is a sampling frequency, fmin is a lower limit frequency of a periodic component to be removed, and α is a parameter according to a desired reduction effect for the periodic component.

10. The DC component extraction apparatus according to claim 4, wherein the comparator is configured to perform processing of switching between the first output signal and the second output signal based on comparison between the first comparison signal and the second comparison signal in a case where a difference between the first comparison signal and the second comparison signal exceeds a preset threshold, and output the same signal as that output one sample before in a case where the difference between the first comparison signal and the second comparison signal is equal to or less than the preset threshold.

11. A demodulation apparatus, comprising:
a first multiplier configured to multiply a first signal by a sine signal of a base frequency to generate a second signal;
a first DC component extractor configured to extract a DC component from the second signal to generate a third signal;
a second multiplier configured to multiply the first signal by a cosine signal of the base frequency to generate a fourth signal;
a second DC component extractor configured to extract a DC component from the fourth signal to generate a fifth signal; and
a calculation unit configured to calculate a gain and a phase of a signal of the base frequency included in the first signal from the third signal and the fifth signal, wherein
the first DC component extractor and the second DC component extractor comprise the DC component extraction apparatus according to claim 1.

12. A DC component extraction method, comprising:
applying a phase shift of 90° to an input signal by a first Hilbert transformer to generate a first filtered signal;
applying a phase shift of 90° to the first filtered signal by a second Hilbert transformer to generate a second filtered signal;
delaying the input signal by a delay time corresponding to the first Hilbert transformer to generate a first delay signal;
delaying the first delay signal by a delay time corresponding to the second Hilbert transformer to generate a second delay signal; and
adding the second filtered signal and the second delay signal.
